(19) United States
(12) Patent Application Publication
(10) Pub. No.: US 2007/0293016 A1
(43) Pub. Date: Dec. 20, 2007

(54) SEMICONDUCTOR STRUCTURE INCLUDING ISOLATION REGION WITH VARIABLE LINEWIDTH AND METHOD FOR FABRICATION THEROF

(75) Inventors: Zhijiong Luo, Carmel, NY (US); Hung Y. Ng, New Milford, NJ (US); Nivo Rovedo, LaGrangeville, NY (US); Phung T. Nguyen, Pleasant Valley, NY (US); William C. Wille, Red Hook, NY (US); Richard Lindsay, Fishkill, NY (US); Zhao Lun, Beacon, NY (US); Yung Fu Chong, Singapore (SG); Siddhartha Panda, Beacon, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignees: INTERNATIONAL BUSINESS MACHINES CORPORATION, Armonk, NY (US); CHARTERED SEMICONDUCTOR MANUFACTURING LTD., Singapore (SG); INFINEON TECHNOLOGIES NORTH AMERICA CORP., San Jose, CA (US)

(21) Appl. No.: 11/424,076

(22) Filed: Jun. 14, 2006

(51) Int. Cl. H01L 21/76

(52) U.S. Cl. 438/424; 438/737; 438/739

(57) ABSTRACT

A semiconductor structure includes a base semiconductor substrate having a doped region located therein, and an epitaxial region located over the doped region. The semiconductor structure also includes a final isolation region located with the doped region and the epitaxial region. The final isolation region has a greater linewidth within the doped region than within the epitaxial region. A method for fabricating the semiconductor structure provides for forming the doped region prior to the epitaxial region. The doped region may be formed with reduced well implant energy and reduced lateral straggle. The final isolation region with the variable linewidth provides a greater effective isolation depth than an actual trench isolation depth.

### BACKGROUND

1. Field of the Invention

The invention relates generally to isolation regions within semiconductor structures. More particularly, the invention relates to enhanced isolation regions within semiconductor structures.

2. Description of the Related Art

With the scaling of semiconductor technology, including in particular CMOS technology, it is becoming more difficult to form isolation regions with adequate isolation between two transistors. A good isolation should ensure high breakdown voltage and low leakage current between two adjacent transistors. Conventional shallow trench isolation regions that incorporate well implant processes for forming isolation regions are often formed only with more difficulty with the scaling down of dimensions.

For example, under circumstances where a shallow trench isolation region is formed particularly deeply within a semiconductor substrate (i.e., on the order of from about 0.5 to about 6 microns), such a deep shallow trench isolation generally also requires a deep doped well implant. Such a deep doped well implant often has a tendency to degrade doped well isolation due to lateral straggling effects.

In addition, if a shallow isolation region is generally shallow (i.e., from about 200 Å to about 0.5 microns), such a shallow depth of the shallow trench isolation region may not provide adequate integrity of isolation.

As semiconductor technology continues to advance, dimensions of semiconductor structures and devices are certain to continue to decrease. As a result, semiconductor structures and methods for fabrication thereof that provide for enhanced isolation at decreased dimensions are desirable.

### SUMMARY OF THE INVENTION

The invention provides a method for fabricating a semiconductor structure. The semiconductor structure is characterized by a semiconductor substrate including, in an upward sequence, a base region, a doped region located over the base region and an epitaxial layer (i.e., region) located over the doped region. An isolation region is located within the doped region and the epitaxial region. The isolation region has a greater linewidth within the doped region than within the epitaxial region. The method for fabricating the semiconductor structure includes forming the doped region prior to the epitaxial region.

A method in accordance with the invention includes forming a sacrificial filler layer within a doped region within a semiconductor substrate. The method also includes forming an epitaxial layer upon the semiconductor substrate and the sacrificial filler layer. The method also includes patterning the epitaxial layer over the sacrificial filler layer to provide an aperture, the aperture has a linewidth less than the sacrificial filler layer. The method also includes etching the sacrificial filler layer to form an enlarged aperture. Finally, the method includes forming a final isolation region within the enlarged aperture. As a result of the foregoing steps, the method provides the semiconductor substrate that includes a base semiconductor region, the doped region located over the base semiconductor region and the epitaxial layer located over the doped region. Also provided is the final isolation region located within the doped region and the epitaxial layer, where the final isolation region has a greater linewidth within the doped region than within the epitaxial layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 9 show a series of schematic cross-sectional diagrams illustrating the results of progressive stages in fabricating a semiconductor structure in accordance with a preferred embodiment of the invention.

### DESCRIPTION OF THE PREFERRED EMBODIMENT

The invention, which includes a semiconductor structure and a method for fabricating the semiconductor structure, is described in further detail below within the context of the drawings described above. The drawings are intended for illustrative purposes, and as such the drawings are not necessarily drawn to scale.

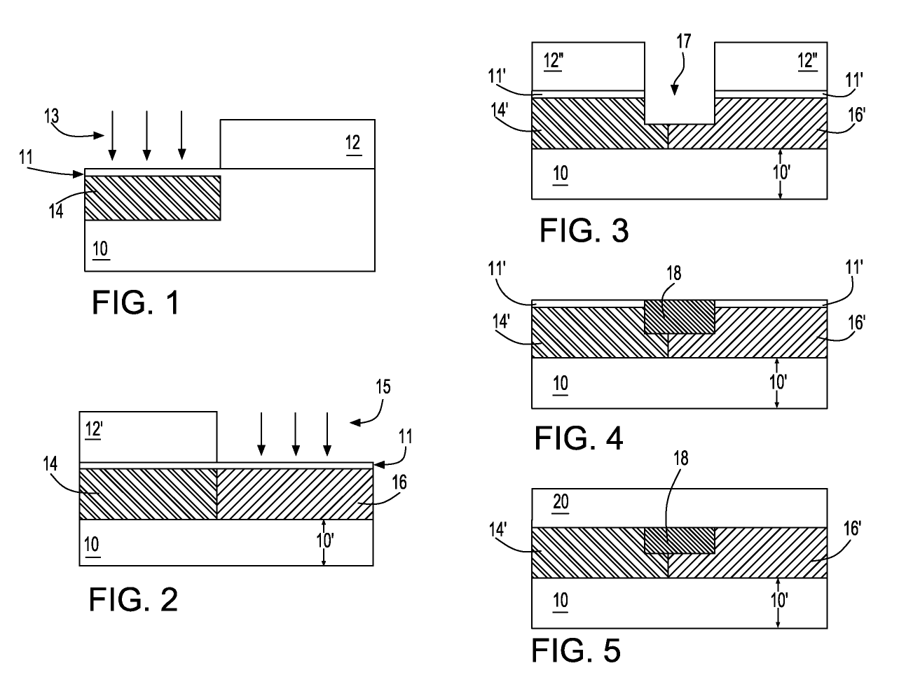

By reference to FIG. 1 to FIG. 9, there is shown a series of schematic cross-sectional diagrams illustrating the results of progressive stages in fabricating a semiconductor structure in accordance with the preferred embodiment of the invention. FIG. 1 shows a schematic cross-sectional diagram of the semiconductor structure at an early stage in the fabrication thereof in accordance with the preferred embodiment.

FIG. 1 shows a semiconductor substrate 10. A first mask layer 12 is located upon the semiconductor substrate 10. A first doped region 14 is located within the semiconductor substrate 10. First dopant ions 13 are used for forming the first doped region 14.

Each of the foregoing semiconductor substrate 10, layer 12, region 14 and ions 13 are generally conventional in the semiconductor fabrication art.

For example, the semiconductor substrate 10 comprises a semiconductor material. Non-limiting examples of semiconductor materials include silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials.

The semiconductor substrate 10 typically comprises a bulk semiconductor substrate, although the invention is not necessarily so limited. Under certain alternative circumstances, the semiconductor substrate 10 may comprise a semiconductor-on-insulator substrate or a hybrid orientation substrate. Either of the latter two semiconductor substrates comprises layered structures.

The first mask layer 12 may comprise any masking material with respect to the first dopant ions 13. Included are hard mask materials and photoresist mask materials, although photoresist mask materials are generally more common. Non-limiting examples of photoresist materials include positive photoresist materials, negative photoresist materials and hybrid photoresist materials. Typically, the first mask layer 12 comprises a photoresist mask material having a thickness from about 500 to about 20000 angstroms.

The first dopant ions 13 and the first doped region 14 may comprise a dopant of any chemical composition or any conductivity type (i.e., dopant polarity). Typically, the first dopant ions 13 and the first doped region 14 comprise an n or p dopant appropriately selected from the group consisting of boron, phosphorus, indium, boron difluoride, antimony and arsenic containing dopants, although the invention is not so limited. Within the embodiment, the foregoing doping conditions are selected to provide an undoped surface region 11 within the semiconductor substrate 10 in addition to the first doped region 14.

FIG. 2 first shows the results of stripping the first mask layer 12 from the semiconductor structure of FIG. 1 and in turn forming the second mask layer 12′ upon the resulting semiconductor structure. The second mask layer 12′ may comprise materials, have dimensions and be formed using methods analogous, equivalent or identical to the first mask layer 12. However, the second mask layer 12′ is located to expose an adjoining and complementary portion of the semiconductor substrate 10.

FIG. 2 also shows a second doped region 16 located within the semiconductor substrate 10 laterally adjoining and adjacent the first doped region 14. FIG. 2 also shows an extension of the undoped surface region 11. The second doped region 16 is implanted into the semiconductor substrate 10 using a dose of second dopant ions 15. The dose of second dopant ions 15 is typically, although not exclusively, of a dopant polarity different than the dose of first dopant ions 13. Ion implantation conditions for the first dopant ions 13 and the second dopant ions 15 are otherwise analogous. The depth of the doped regions 14/16 is about 100 angstroms to about 5000 angstroms and the dopant concentration therein is from about 1e12 to about 1e20 dopant atoms per cubic centimeter. Similarly with the first dopant ions 13, implanting conditions for the second dopant ions 15 are selected to provide the undoped surface region 11. FIG. 2 also shows a base semiconductor region 10′ portion of the semiconductor substrate 10 beneath the doped regions 14/16.

FIG. 3 first shows the results of stripping the second mask layer 12′ from the semiconductor structure of FIG. 2. The second mask layer 12′ may be stripped using methods and materials analogous, equivalent or identical to the methods and materials used for stripping the first mask layer 12.

FIG. 3 also shows third mask layer 12″ located upon the semiconductor structure of FIG. 2, absent the second mask layer 12′. The third mask layer 12″ may also comprise a hard mask material or a photoresist mask material. Photoresist mask materials are more common. As is illustrated in FIG. 3, the third mask layer 12′ is used as an etch mask for etching a trench 17 into the semiconductor substrate 10 at a location where first doped region 14 and second doped region 16 adjoin. But in general, the trench 17 is not limited to the location at where first doped region 14 and second doped region 16 adjoin. The trench 17 can be totally surrounded by the first doped region 16 or the second doped region 14. The foregoing etching of the trench 17 yields the first doped region 14′ and the second doped region 16′. The etching of the trench 17 is undertaken using etch methods that are conventional in the semiconductor fabrication art. Plasma etch methods are common insofar as they generally provide straight sidewalls to the trench 17. Under certain circumstances, wet chemical etch methods may also be used.

FIG. 4 shows a sacrificial filler layer 18 located within the trench 17. The sacrificial filler layer 18 typically comprises a dielectric material, although sacrificial filler layers comprising semiconductor materials and conductor materials may also be used. Dielectric materials typically comprise oxides, nitrides or oxynitrides of silicon, as well as composites thereof and laminates thereof. Oxides, nitrides or oxynitrides of other elements are not excluded. Typically, the sacrificial filler layer 18 is formed using a blanket layer deposition and subsequent planarization. Non-limiting examples of planarizing methods include purely mechanical planarizing methods, as well as chemical mechanical polish planarizing methods. Chemical mechanical polish planarizing methods are generally more common.

FIG. 5 shows an epitaxial layer 20 (i.e., an epitaxial region) located upon the semiconductor structure of FIG. 4. The epitaxial layer 20 incorporates undoped surface layer 11 portions of the semiconductor substrate 10 located above the first doped region 14 and the second doped region 16. The epitaxial layer 20 may comprise any of the semiconductor materials from which is comprised the semiconductor substrate 10. The semiconductor substrate 10 and the epitaxial layer 20 need not comprise the same semiconductor material. Typically, the epitaxial layer 20 has a thickness from about 100 to about 5000 angstroms. The epitaxial layer 20 is typically formed using a chemical vapor deposition method.

The semiconductor structure of FIG. 5 thus shows in upward sequence, a base semiconductor region 10′, a doped region 14′/16′ located thereover and an epitaxial layer 20 (i.e., epitaxial region) located thereover.

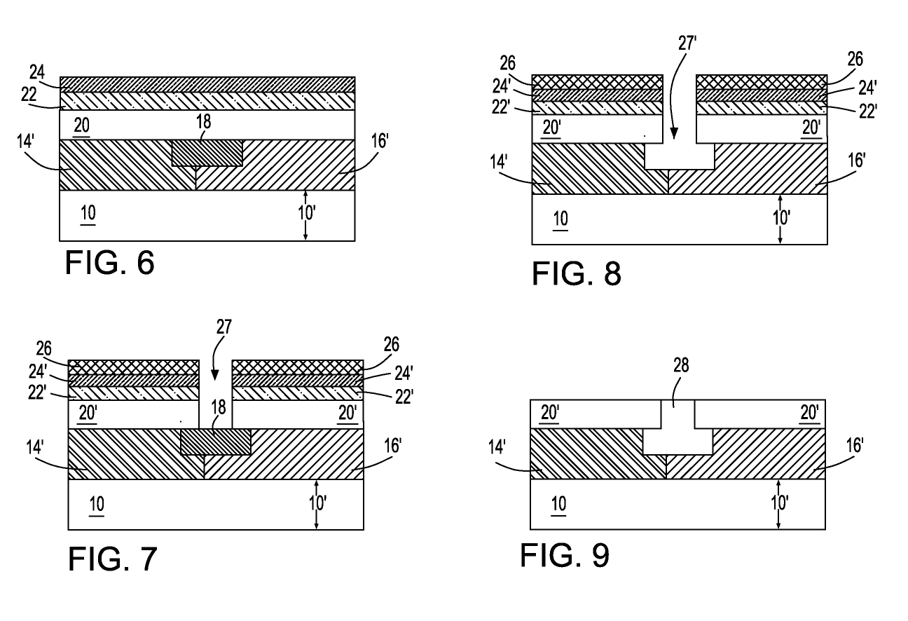

FIG. 6 shows a first pad dielectric 22 located upon the epitaxial layer 20. FIG. 6 also shows a second pad dielectric 24 located upon the first pad dielectric 22. The first pad dielectric 22 and the second pad dielectric 24 are generally formed of different dielectric materials. Non-limiting examples of candidate dielectric materials include oxides, nitrides and oxynitrides of silicon. The invention is not limited to selections from only the foregoing materials. Alternative dielectric materials may also be used.

Typically, the first pad dielectric 22 comprises an oxide dielectric material and the second pad dielectric 24 comprises a nitride dielectric material. The foregoing pad dielectric materials may be formed using any of several methods. Non-limiting examples include thermal or plasma oxidation or metrication methods, chemical vapor deposition methods and physical vapor deposition methods.

FIG. 7 shows fourth mask layer 26 located upon the semiconductor structure of FIG. 5. Similarly with previous mask layers, the fourth mask layer 26 may comprise either hard mask materials or photoresist mask materials. Photoresist mask materials are more common. Dimensions are similar to those used for previous mask layers.

FIG. 7 also shows the results of patterning the second pad dielectric 24, the first pad dielectric 22 and the epitaxial layer 20 while using the fourth mask layer 26 as a mask. The patterning yields the second pad dielectric 24′, the first pad dielectric 22′ and the epitaxial layer 20′ which in the aggregate define an aperture 27. The foregoing patterning is typically effected while using a plasma etch method that provides a series of straight sidewalls to the second pad dielectric 24′, the first pad dielectric 22′ and the epitaxial layer 20′. As is illustrated within the schematic cross-sectional diagram of FIG. 7, the aperture 27 has a narrower linewith than the sacrificial filler layer 18. The aperture 27 is typically also located nominally centered with respect to the sacrificial filler layer 18. Typically, the aperture 27 has a linewidth from about 10 to about 500 nm and the sacrificial filler layer 18 has a linewidth from about 11 to about 800 nm

FIG. 8 shows the results of etching the sacrificial filler layer 18 from the semiconductor structure of FIG. 7. The sacrificial filler layer 18 may be etched using an isotropic etchant while remaining portions of the semiconductor substrate 10, including the first doped region 14′, the second doped region 16′ and the epitaxial layer 20′ serve as etch stop layers. Suitable isotropic etchants include wet chemical etchants, Certain plasma etchants may also be used.

The etching yields an inverted “T” shaped aperture 27′ having a wider bottom portion in comparison with a top portion.

FIG. 9 first shows the results of stripping the fourth mask layer 26, the second pad dielectric 24′ and the first pad dielectric 22′ from the semiconductor structure of FIG. 8. The foregoing layers may be stripped using methods and materials that are conventional in the semiconductor fabrication art.

FIG. 9 finally shows the results of forming a final isolation region 28 into the inverted “T” shaped aperture defined by the epitaxial layer 20′ and the doped regions 14′ and 16′. The final isolation region 28 may comprise any of the several isolation materials that are used for forming isolation regions. Included are oxides, nitrides and oxynitrides of silicon, as well as laminates thereof and composites thereof. Oxides, nitrides and oxynitrides of other elements are not excluded. A wider portion of the final isolation region 28 is located within the doped region 14′/16′ and a narrower portion of the final isolation region 28 is located within the epitaxial region 20′.

FIG. 9 shows a semiconductor structure in accordance with a preferred embodiment of the invention. The semiconductor structure comprises a generally layered structure comprising a base semiconductor region 10′, a doped region 14′/16′ located thereover and an epitaxial region 20′ located further thereover. A final isolation region 28 is located within the doped region 14′/16′ and the epitaxial region 20′, and not extending into the base semiconductor region 10′. The final isolation region 28 has a narrower linewidth within the epitaxial region 20′ than within the doped region 14′/16′. While the invention illustrates the final isolation region 28 as formed with an inverted “T” shape, the invention also contemplates isolation regions with alternative shapes that are wider at a bottom region than at a top region, but not necessarily of an inverted “T” shape. Long neck bottle shapes are an example. Similarly, while the embodiment illustrates a wider portion of a final isolation region 28 formed into a location where a pair of doped regions adjoin, an alternative embodiment would place the wider portion of a final isolation region 28 into only a single doped region.

The semiconductor structure of FIG. 9 is formed using a method that provides for forming the doped regions 14′/16′ prior to forming the epitaxial layer 20′. By forming the doped regions 14′/16′ prior to the epitaxial layer 20′, doped region 14′/16′ implant energy is reduced and thus a lateral straggle is reduced. In addition, the inverted “T” shaped shallow trench final isolation region 28 increases an effective shallow isolation trench depth without increasing an actual shallow isolation trench depth.

The preferred embodiment of the invention is illustrative of the invention rather than limiting of the invention. Revisions and modifications may be made to methods, materials, structures and dimensions of a semiconductor structure in accordance with the preferred embodiment of the invention while still providing a semiconductor structure in accordance with the invention, further in accordance with the accompanying claims.

What is claimed is:

1. A method for fabricating a semiconductor structure comprising:
(a) forming a sacrificial filler layer within a doped region within a semiconductor substrate;
(b) forming an epitaxial layer upon the semiconductor substrate and the sacrificial filler layer;
(c) patterning the epitaxial layer over the sacrificial filler layer to provide an aperture, the aperture having a linewidth less than the sacrificial filler layer;
(d) etching the sacrificial filler layer to form an enlarged aperture; and
(e) forming a final isolation region within the enlarged aperture, wherein the foregoing steps (a)-(e) provide:
the semiconductor substrate comprising a base semiconductor region, the doped region located over the base semiconductor region and the epitaxial layer located over the doped region; and
the final isolation region located within the doped region and the epitaxial layer, where the final isolation region has a greater linewidth within the doped region than within the epitaxial layer.

2. The method of claim 1 wherein the etching the sacrificial filler layer provides the enlarged aperture with an inverted “T” shape.

3. The method of claim 1 wherein etching the sacrificial filler layer provides the enlarged aperture with a wider linewidth within the doped region than within the epitaxial layer.

4. The method of claim 1 wherein the forming the final isolation region within the doped region provides for forming the final isolation region within a laterally adjoining pair of doped regions of different polarity.
